(19) United States
(12) Patent Application Publication
(10) Pub. No.: US 2004/0259284 A1
(43) Pub. Date: Dec. 23, 2004

(54) Method of increasing the luminescent bandwidth of photoelectric semiconductor device by separate confinement heterostructure

(75) Inventor: Ching-Fuh Lin, Taipei (TW)

Correspondence Address: Bo-In Lin, 13445 Mandoli Drive, Los Altos Hills, CA, 94022, US

(73) Assignee: National Taiwan University

(21) Appl. No.: 10/729,411

(22) Filed: Dec. 4, 2003

(30) Foreign Application Priority Data
Jun. 20, 2003 (TW) 92116753

(51) Int. Cl. H01L 21/00

(52) U.S. Cl. 438/47

(57) ABSTRACT

Disclosed is a method of increasing the luminescent bandwidth of a photoelectric semiconductor device. Such method uses separate confinement heterostructure (SCH) region having a shortened width to reduce the time for holes to pass therethrough and curtail the difference between the time for holes to enter the quantum well structures and the time for electrons to enter the quantum well structures, and thereby an even uniform carrier distribution can be obtained. Accordingly, each quantum well structure is able to receive carrier and a better luminescent bandwidth can be produced. Such method can be applied in the production of wavelength-tunable semiconductor laser device to enlarge the tunable range of wavelength of the semiconductor laser device, and also such method is quite convenient for testing semiconductor laser device. Furthermore, such method can also be applied in an optical communication system to replace other versatile components, and thus reduce the cost necessary for system integration.

### BACKGROUND OF THE INVENTION

1. Field of the Invention

The present invention is generally related to a technique of tuning the luminescent bandwidth of a photoelectric semiconductor device, and more particularly to a technique of increasing the luminescent bandwidth of a photoelectric semiconductor device.

2. Description of the Related Art

With the prosperity of the Internet age, transmitters, receivers or switchers that are indispensable for an optical fiber network have made themselves the keys in the photoelectric-related research study. Because a photoelectric semiconductor device is characterized in terms of a thin-and-small volume, capability of generating optical signals of high luminescent power, high switching speed, and high stability (including durability against temperature variation and long operating time), it has been generally acknowledged as an essential element for optical fiber communication.

For example, semiconductor optical amplifier (hereinafter “SOA”) and superluminescent diode (hereinafter “SLD”) are also employed for implementing the function of amplifying an optical relay signal and constituting a photo switch. Unfortunately, a conventional SOA only provides a limited bandwidth of 40 nm or so, which falls short of the requirements for a broadband optical fiber communication system. On the other hand, although an Er-doped fiber amplifier (hereinafter “EDFA”) has been commonly used for the amplification of the optical relay signal in an optical communication system, its available bandwidth is still limited and confined between C-band and L-band (1525 nm-1605 nm). However, the optical signal transmitted using another important band (around 1300 nm) in the optical fiber communication can scarcely be amplified by EDFA. In this manner, the future optical communication system can not rely upon EDFA solely.

Referring to FIG. 1, an absorption spectrum of the current optical fiber is shown. As indicated in FIG. 1, the solid curve located in the bottom represents a single mode optical fiber with 4% germanium dioxide (GeO₂) doped in its core portion, while the dashed curve located in the top represents a multi mode optical fiber. The peak value of the attenuation located in correspondence with the wavelength of 1400 nm or so is emerged because of the presence of water molecules in the optical fiber glass. This absorption peak has been removed by the new technology pioneered by Lucent Technology at 2000, and therefore the optical fiber can provide a low loss transmission over a wide range of wavelength from 1250 nm to 1650 nm.

The fabrication technique of the optical fiber today is continuously improving its completeness with each passing day, and the usable frequency band of optical communication system has covered the range from 1200 nm to 1650 nm. However, although EDFA has a better coupling efficiency with optical fiber, it only provides a limited gain bandwidth. In the range of wavelength of C-band and L-band, EDFAs with different gain bandwidths are necessarily required, and the costs of stock management and fabrication are prohibitive accordingly. These disadvantageous factors pertinent to EDFA have been considered as one of the major drawbacks as it is employed in an optical fiber communication system. What is worse, the frequency band in the proximity of 1300 nm is incompatible with any kind of EDFA. As a result, if it is intended to use a semiconductor optical amplifier as the repeater in an optical fiber communication system, it had better to be able to provide a robust and sufficient gain as its luminescent bandwidth lies between 1250 nm and 1650 nm. Unfortunately, the conventional photoelectric semiconductor device only can provide a luminescent bandwidth of 40 nm or so, which is unsatisfactory for broadband optical fiber communication system.

Furthermore, the electric property of a semiconductor quantum-well laser or the like is eminent for a low threshold current density, a low temperature sensitivity, and a larger gain bandwidth, which offers a better performance than a solid state semiconductor laser device. This is because the epitaxy layer of the quantum well is extremely thin. The current semiconductor laser, regardless its purpose, is manufactured by growing semiconductor quantum well structures via either metal organic chemical vapor deposition (hereinafter “MOCVD”) or molecular beam epitaxy process and other semiconductor manufacturing process.

The recent research report points out that the carriers excited by current injection do not result in a uniform distribution in multi-layer quantum well structures. If it is desired to increase the gain bandwidth, i.e. increase the luminescent bandwidth of a semiconductor optical amplifier, the effect of non-uniform carrier distribution has to be taken into consideration. In the past, some scientists attempt to increase the luminescent bandwidth of a photoelectric semiconductor device by using asymmetrical multi-layer quantum well structures. However, the effect of non-uniform carrier distribution was never taken into consideration. These prior exertions did not make fruitful achievements after all.

In consideration of the deficiencies of the conventional relay optical signal amplifier, the present invention presents a method of increasing the luminescent bandwidth of a photoelectric semiconductor device. Such method basically utilizes multi-layer quantum well structures having different widths such that the energy levels of each quantum well structure can engage with one another. Further, the present invention takes the property of non-uniform carrier distribution within quantum well structures into consideration, and tackle this problem by using separate confinement heterostructure (SCH) having a shortened width to produce an even uniform carrier distribution within quantum well structures, and an ultra-wide luminescent bandwidth can be obtained with ease. The frequency band of the semiconductor optical amplifier manufactured thereby can cover a very large bandwidth from 1250 nm to 1650 nm.

### SUMMARY OF THE INVENTION

A first object of the present invention is to provide a method of increasing the luminescent bandwidth of a photoelectric semiconductor device through the use separate confinement heterostructure (SCH) having a short width so as to shorten the time for holes to pass through SCH region and diminish the difference between the time for holes to enter the quantum well structures and the time for electrons to enter the quantum well structures. The carrier distribution within the quantum well structures can become even uniform and a large gain bandwidth can be produced so as to increase the luminescent bandwidth of the photoelectric semiconductor device.

Another object of the present invention is to provide a method of increasing the luminescent bandwidth of a photoelectric semiconductor device by separate confinement heterostructure which can achieve a large luminescent bandwidth and a low operating current.

Another still object of the present invention is to provide a method of increasing the luminescent bandwidth of a photoelectric semiconductor device by separate confinement heterostructure. The method according to the present invention is based on the technique of manipulating quantum well structures having different widths to increase the luminescent bandwidth of a photoelectric semiconductor device, so that the dominant carrier controlling the two-dimensional carrier distribution within the quantum well structures can be selected from either holes or electrons, thereby achieve a larger gain bandwidth and a better temperature coefficient.

To these ends, the present invention presents multi-layer quantum well structures having different widths or constituent materials, wherein the two-dimensional carrier distribution therein is controlled by holes or electrons by tuning the width of separate confinement heterostructure (SCH) region. More precisely, the width of separate confinement heterostructure (SCH) region is shortened in compliance with the mobility of holes so that the time for holes to enter the quantum well structures is approximately equal to the time for electrons to be captured by the quantum well structures, which can satisfy the criterion of I the time for holes to enter the quantum well structures (τ_{p,diffusion})—the time for electrons to be captured by the quantum well structure (τ_{n,cap})|<1 picosecond.

By using the above-described technique, photoelectric semiconductor device such as semiconductor optical amplifier/high luminescent power photodiode/semiconductor laser with a wide gain bandwidth, better temperature coefficient and better switching capability can be attained without effort. Moreover, the tunable range of the wavelength of a laser device can be significantly enlarged, which is quite convenient for testing the optical communication system. Such technique can be applied to replace other versatile components in an optical communication system and reduce the cost necessary for system integration.

The foregoing and features and advantages of the present invention will become more apparent through the following descriptions with reference to the accompanying drawings.

### BRIEF DESCRIPTION OF THE DRAWINGS

FIG. 1 is an absorption spectrum of the current optical fiber.

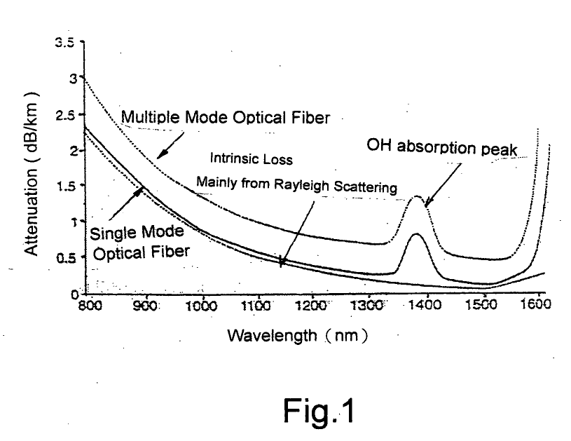

FIG. 2 is a characteristic plot illustrating the relationship between the energy of the quantum well structures and the density of states.

FIG. 3 shows the epitaxy structure of the semiconductor optical amplifier/high luminescent power photodiode A1.

FIG. 4 shows the epitaxy structure of the semiconductor optical amplifier/high luminescent power photodiode A4.

FIG. 5 shows the luminescent spectrum of the semiconductor optical amplifier/high luminescent power photodiode A1 under different current conduction.

FIG. 6 shows the luminescent spectrum of the semiconductor optical amplifier/high luminescent power photodiode A4 under different current conduction.

FIG. 7 illustrates the relationship of the spectral width at half maximum (FWHM) bandwidth versus injected current.

### DETAILED DESCRIPTION OF THE INVENTION

Consider a photoelectric semiconductor device, if it is desired to use a semiconductor optical amplifier as a repeater in an optical fiber communication system, it had better to be able to render a robust and sufficient gain as its luminescent bandwidth lying between 1250 nm and 1650 nm. However, a conventional semiconductor optical amplifier only provides a luminescent bandwidth of 40 nm or so, and thus it falls short of the requirements for a broadband optical fiber communication system, as mentioned above.

Besides, it is clearly known from the antecedent research achievements that the carrier distribution of related semiconductor material extensively used in optical communication system is quite non-uniform in multi-layer quantum well structures, and it will fluctuate drastically depending on the variation of the configuration, arrangement and composition of the quantum well structures. These variable factors have to be taken into consideration during the design stage of a photoelectric semiconductor device for optical fiber communication system. As a result, it is intended to dwell on the factors that are to be taken into consideration during the design stage of a photoelectric semiconductor device for an ultra-wideband framework first, and the effect caused by the width of the separate confinement heterostructure will be discussed later.

To design multi-layer quantum well structures having different widths for ultra-wideband communication, the following aspects should be synthetically considered:

1. The energy levels of quantum wells having the same width: The purpose of designing a photoelectric semiconductor device for use in broadband communication can be achieved by accommodating desirable luminescent wavelengths by stacking multi-layer quantum well structures having different widths and thereby. However, the following situations should be considered:

a. If the quantum well bottoms and the materials of the barrier layer of these quantum wells having different widths are identical to each other, it can be understood according to the deduction from quantum physics that the quantum well structures having a large width occupy a low quantized energy level and a long luminescent wavelength. On the contrary, the quantum well structures having a small width occupy a high quantized energy level and a short luminescent wavelength. The result reveals that if it is required to achieve the same gain value, the quantum well structures having a large width require a low carrier concentration according to the detailed calculation result derived based on the gain spectrum. However, this would affect the final luminescent spectrum.

b. If the quantum well bottoms or barriers of multi-layer quantum well structures are made of different materials, the flexibility of design can be aggrandized. That is, one may design multi-layer quantum well structures having different luminescent wavelengths and similar quantized energy levels. In this way, the gain bandwidth can be increased effectively, and the gain values are quite unanimous with each other as the gain value is positive.

c. If the fact that the radiations from quantum well structures having a high quantized energy level occupies a high energy, and it is prone to be reabsorbed by quantum well structures having a low quantized energy level is taken into consideration, the number of quantum well structures having a high energy level should be set more when the number of the multi-layer quantum well structures having different widths are to be determined during design stage. However, the actual allocation of the number of the multi-layer quantum well structures should be determined according to the calculation result derived based on the gain spectrum.

2. The length of the SCH structure: In a quantum well structure, the electron-hole pairs that are excited by current injection are injected from P and N junctions respectively, and then enter the active region via separate confinement heterostructures and recombine here to emit lights therefrom. Hence, the mobility of the carrier in SCH region governs its ability to control the two-dimensional carrier distribution within the quantum well structures.

a. If the electrons enter the quantum well structures earlier, electrons will become the dominant carrier controlling the two-dimensional carrier distribution within the quantum well structures. The final two-dimensional carrier distribution within the quantum well structures depends on the spatial distribution of electrons (since the electrons are injected into the quantum well through N junction, the concentration of electrons will be high in the proximity of N junction) and will be allocated correspondingly according to the charge neutrality principle. The same theorem may apply when holes are the dominant carriers. The following arithmetic model can be used to determine which carrier is the dominant carrier:

$${τ}_{LF} = {τ}_{p , diffusion} + {τ}_{n , diffusion} + {τ}_{cap , p} + {τ}_{cap , n} = \frac{{d}_{p}^{2}}{4 {D}_{p}} + \frac{{d}_{n}^{2}}{4 {D}_{n}} + \frac{{d}_{p} {τ}_{cp}}{W} + \frac{{d}_{n} {τ}_{cn}}{W}$$

where dₚ(dₙ) stands for the distance that the hole (electron) diffused to the quantum well, i.e. the length of the SCH region, Dₚ and Dₙ stand for the diffusion coefficients of semiconductor material, W is the width of the quantum well structures, and dₚτ_{cp} and dₙτ_{cn} are respectively the electron capture time and hole capture time according to the calculation result derived based on quantum physics. Therefore, the four temporal variables located on the left side of the equal sign respectively denote the diffusion time of the holes in the SCH region, the diffusion time of the electrons in the SCH region, the equivalent hole capture time of the quantum well structures, and the equivalent electron capture time of the quantum well structures. Moreover, in order to take the adverse effect into account that the electrons that are not captured by the quantum well structures will accumulate in the SCH region and prolong the diffusion time, the equivalent carrier capture time by the quantum well structures should be equal to the product of the carrier capture time by the quantum well structures multiplied by a volume ratio of dₚ(dₙ)/W.

b. The temporal variables associated with holes in the above equation (the hole diffusion time+the equivalent hole capture time) are defined as the time between the holes injecting into the SCH region and being captured by the quantum well structures to enter the two-dimensional energy level τ_{p,total}=τ_{p,diffusion}+τ_{cap,p}, and it is to be compared with the time between the electrons injecting into the SCH region and being captured by the quantum well structures to enter the two-dimensional energy level τ_{n,total}=τ_{n,diffusion}+τ_{cap,n} (the electron diffusion time+the equivalent electron capture time). If τ_{p,total}>τ_{n,total}, the electron will enter the two-dimensional energy level of the quantum well structures earlier, and the concentration of electrons in the proximity of N-type semiconductor side is high. The holes that enter the two-dimensional energy level of the quantum well structures later will present similar distribution according to the distribution of electrons. Thus, the concentration of two-dimensional carriers within the quantum well structures in the proximity of N-type semiconductor side is high. On the contrary, if τ_{n,total}>τ_{p,total}, the holes will enter the two-dimensional energy level of the quantum well structures earlier, and the concentration of holes in the proximity of P-type semiconductor side is high. The electrons that enter the two-dimensional energy level of the quantum well structures later will present similar distribution according to the distribution of holes. Thus, the concentration of two-dimensional carriers within the quantum well structures in the proximity of P-type semiconductor side is high. In comparison between the two foregoing situations, if holes are selected as the dominant carrier, its great equivalent mass will debase its temperature sensitivity, resulting in a better temperature coefficient. On the contrary, if electrons are selected as the dominant carrier, the carrier distribution within the quantum well structures will be even uniform, resulting in a larger gain bandwidth.

c. The uniformity of carriers within the quantum well structures: The uniformity of carriers within the quantum well structures is related to the carrier capture rate in quantum well structures, namely, the capability of the quantum well structures in capturing carriers is connected with the two-dimensional density of states of the quantum well structures. The higher the two-dimensional density of states of the quantum well structures is, the better the capability of the quantum well structures in capturing carriers is. The carrier distribution within the quantum well structures having different widths can be affected based on the uniformity of carrier distribution within the quantum well structures as well as the selection of dominant carrier. If a large luminescent bandwidth is desired, the carriers have to distribute uniformly within the quantum well structures having different widths. However, this would sacrifice some luminescent properties of such photoelectric device, for example, the luminescent efficiency.

d. The following factors would impact the uniformity of carrier distribution within quantum well structures:

1. The composition of quantum well bottom and barrier, the width of quantum well structures, and the arrangement of the quantum well structures having different widths: According to experimental analysis, the composition of the quantum well bottom and barrier will affect the capability of the quantum well structures in confining the carriers based on the two-dimensional and three-dimensional density of states, and bring influence on the final two-dimensional carrier distribution (including the selection of dominant carrier). The width of the quantum well structure will influence the two-dimensional density of states of the quantum well structure, and further influence the carrier distribution and uniformity of carrier distribution within the quantum well structure.

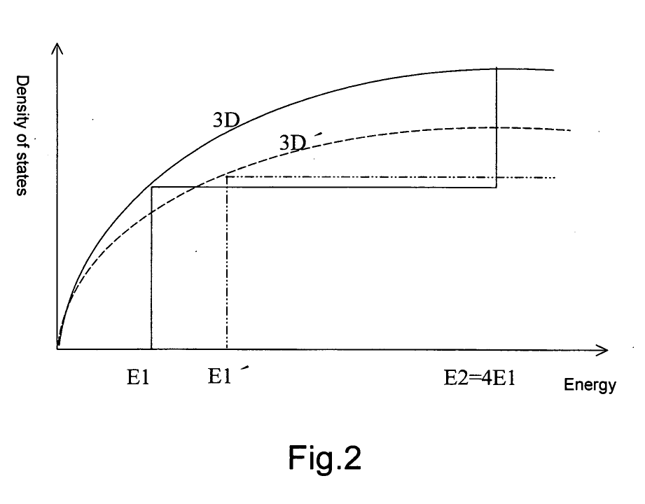

FIG. 2 is a characteristic plot illustrating the relationship between the energy of the quantum well structures and the density of states. As shown in this plot, different parabolas represents different semiconductor materials, i.e. the energy levels of the quantum well structures form step functions under different three-dimensional energy level densities. Parabolas 3D and 3D′ denotes different semiconductor materials, and E1 and E1′ denote different widths of quantum well structures. If the quantized energy levels of the quantum well structures are almost the same with each other, the difference between the two-dimensional density of states mainly comes from the difference between the substantial composition. Further, the density of states is influential in the uniformity of two-dimensional carrier distribution. It can be understood that the two-dimensional density of states has a familiar relationship with the width and the composition of quantum well structures, and these factors have to be taken into consideration in the design stage.

2. The width and height of barrier: In multi-layer quantum well structures, the wider the barrier between the quantum wells is, the better uniformity the carrier distribution within the multi-layer quantum well structures has, the lower the barrier between quantum well structures is, and the better uniformity the two-dimensional carrier distribution within the quantum well structures has.

3. The width of SCH region: Because the mobility of electrons is far larger than holes, electrons can diffuse to the quantum well structures promptly. In general, the diffusion coefficient of electrons is thirty times larger than that of holes. Although electrons can be captured into the quantum well structures earlier, the capture process will not perform before the electrons reach the quantum well structures. If it is desired to let the electrons and holes to enter the quantum well structures almost at the same time, the time for holes to reach the quantum well structures can not be too much longer than the electron diffusion time to the quantum well structures. Thus, the width of SCH region plays a significant role in determining the -diffusion time of the electrons and holes to the quantum well structures. In brief, the sum of the hole diffusion time plus the hole capture time has to be greater than the sum of the electron diffusion time plus the electron capture time. Although the hole capture time is shorter than the electron capture time, holes are likely to reach the quantum well structures later than the electrons for 10 picoseconds because of its long diffusion time. Even though the hole capture time is very short (can be shorter than 1 picosecond), the sum of the hole diffusion time plus the hole capture time is still far greater than the sum of the electron diffusion time plus the electron capture time, and so the electron is selected as the dominant carrier in the quantum well structures, resulting in a non-uniform carrier distribution within the quantum well structures. The width of the SCH region has to be appropriately selected to effect the criterion that the sum of the electron diffusion time plus the electron capture time is approximately equal to the sum of hole diffusion time plus the hole capture time.

4. The effect of dopant ion diffusion: When a semiconductor device is doped into a P-type semiconductor, the dopant ions are apt to diffuse. They may penetrate into the quantum well structures during epitaxy process or manufacturing process, which in turn lower the gain provided by the quantum well structures located in the proximity of P-type semiconductor side. Therefore, the adverse effects caused by dopant diffusion have to be eliminated.

Since the photoelectric semiconductor device for ultra-wideband application would be affected by a plethora of factors, the present invention is concentrated on the provision of a technique of increasing the luminescent bandwidth of a photoelectric semiconductor device by controlling the width of SCH structure within the quantum well structures having different widths.

The method of increasing the luminescent bandwidth of a photoelectric semiconductor device according to the present invention is based the rationale of: controlling the width of SCH structure and thereby producing multi-layer quantum well structures having different widths wherein the two-dimensional carrier distribution therein is controlled by electrons or holes, and the width of the SCH region is shortened to match with hole's mobility so that the time for holes to enter the quantum well structures is approximate to the time for electrons to be captured by the quantum well structures. The relationship between the time for holes to enter the quantum well structures and the time for electrons to be captured by the quantum well structure should satisfy the flowing formula: |the time for holes to enter the quantum well structures (τ_{p,diffusion)}—the time for electrons to be captured by the quantum well structure (τ_{n,cap)}|<1 picosecond. The purpose of controlling the widths of different SCH regions is to limit the time for holes to reach the quantum well structures within 5 picoseconds. Also, the energy levels of quantum well structures having different widths that allows desirable luminescent wavelengths is formed by stacking multi-layer quantum well structures having different widths or constituent materials together.

The photoelectric semiconductor device according to the present invention may either be a semiconductor optical amplifier, a superluminescent diode, or a semiconductor laser, and is adapted for III-V semiconductors used in an optical communication system. The quantum well structures may also be made of the semiconductor materials including II-VI semiconductors, IV semiconductors, the compound of IV semiconductors and III-V semiconductors, the compound of IV semiconductors and II-VI semiconductors, the compound of III-V semiconductors and II-VI semiconductors, and the compound of IV semiconductors, III-V semiconductors and II-VI semiconductors, and may be made of two or more chemical elements. The SCH structure is composed of the semiconductor materials including III-V, II-VI semiconductors, IV semiconductors, the compound of IV semiconductors and III-V semiconductors, the compound of IV semiconductors and II-VI semiconductors, the compound of III-V semiconductors and II-VI semiconductors, and the compound of IV semiconductors, III-V semiconductors and II-VI semiconductors, and alternatively may be made of two or more chemical elements and may be composed by two or more chemical elements.

When the method of controlling the width of SCH regions is put into practice, the width of the SCH region located in the proximity of P-type semiconductor side is tailored to limit the time for holes to reach the quantum well structures within 5 picoseconds. In order to limit the time difference between the time for holes to reach the quantum well structures and the time for electrons to reach the quantum well structures within 3 picoseconds, the width of the SCH region located in the proximity of N-type semiconductor side is set larger than the width of the SCH region located in the proximity of P-type semiconductor side. Specifically, an extremely thin N-type semiconductor is included within the SCH region located in the proximity of P-type semiconductor side, and has a width not greater than 5 nm. This extremely thin N-type semiconductor is used to prevent dophant ions of the P-type semiconductor side from penetrating into the quantum well structures.

In addition, the above equation may be applied to determine whether electrons or holes serves as the dominant carrier within the quantum well structures according to the present invention. If the time between the holes injecting into the SCH region and being captured by the quantum well structures to enter the two-dimensional energy level τ_{p,total}=τ_{p,diffusion}+τ_{cap,p}<the time between the electrons injecting into the SCH region and being captured by the quantum well structures to enter the two-dimensional energy level τ_{n,total}=τ_{n,diffusion}+τ_{cap,n}, the holes are selected as the dominant carrier. By the same token, if the time between the holes injecting into the SCH region and being captured by the quantum well structures to enter the two-dimensional energy level τ_{p,total}=τ_{p,diffusion}+τ_{cap,p}> the time between the electrons injecting into the SCH region and being captured by the quantum well structures to enter the two-dimensional energy level τ_{n,total}=τ_{n,diffusion}+τ_{cap,n}, the electrons are selected as the dominant carrier, which implies that the carrier distribution within the quantum well structures will become even uniform, and the luminescent bandwidth of the photoelectric semiconductor device formed thereby will become larger.

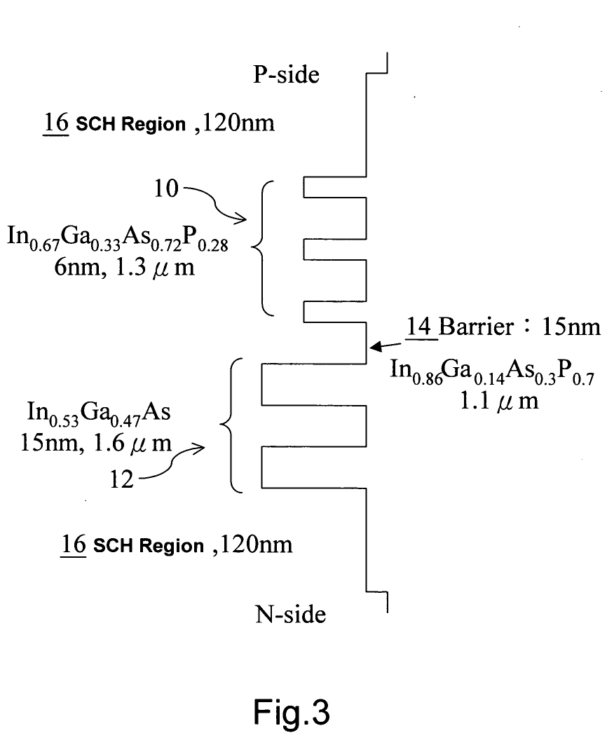

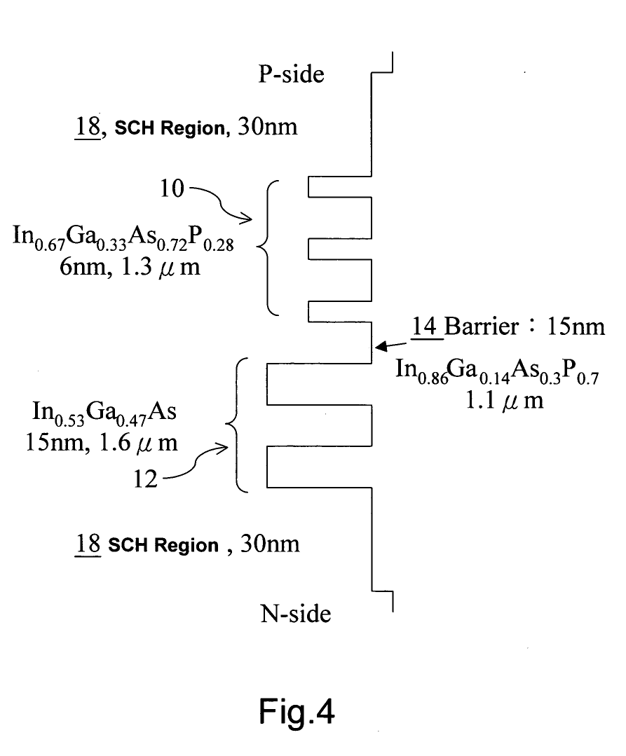

In order to testify the influence of the width of the SCH region, an experiment has been taken to further validate the effectiveness of the present invention. FIGS. 3 and 4 show the epitaxy structure of the semiconductor optical amplifier/high luminescent power photodiode using two different semiconductor materials and multi-layer quantum well structures having different SCH widths based on the teachings according to the present invention. The semiconductor materials used to form the quantum well structures 10,12 are respectively In_{0.67}Ga_{0.33}As_{0.72}P_{0.28} and In_{0.53}Ga_{0.47}As, and the estimated luminescent wavelength are respectively rated at 1.3 μm and 1.6 μm. The semiconductor material used to form the barrier 14 is In_{0.86}Ga_{0.14}As_{0.3}P_{0.7}. The SCH region 16 shown in FIG. 3 has a width of 120 nm, and is named with the designation A1. The SCH region 18 shown in FIG. 4 has a width of 30 nm, and is named with the designation A4.

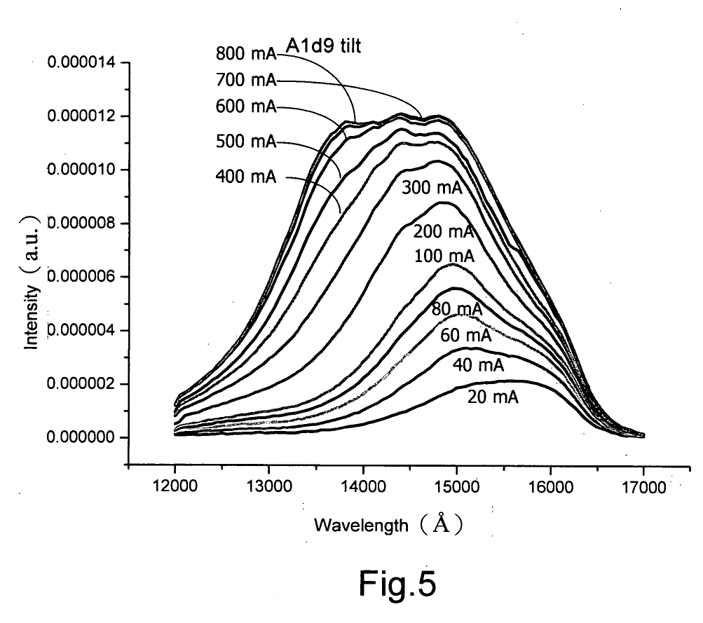

When the semiconductor optical amplifier/high luminescent power photodiode A1 of FIG. 3 is undergoing different current conductions, it can be seen from the luminescent spectrum of FIG. 5 that the radiation having a wavelength ranged between 1.3 μm and 1.6 μm is gradually emitted out. The possible wavelength of luminescent radiation covers the range from 1.3 μm and 1.6 μm, and even broader.

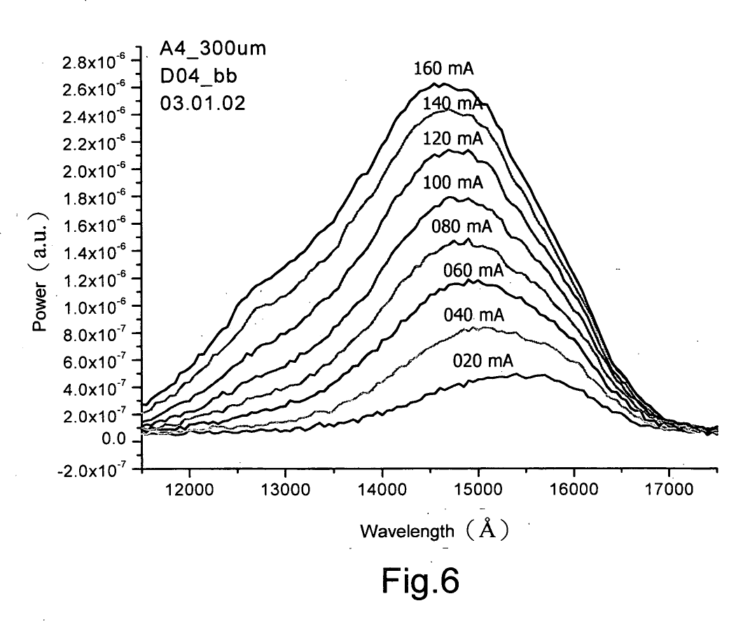

When the semiconductor optical amplifier/high luminescent power photodiode A4 of FIG. 4 is undergoing different current conductions, it can be seen from the luminescent spectrum of FIG. 6 that the radiation having a wavelength ranged between 1.3 μm and 1.6 μm is gradually emitted out. The possible wavelength of luminescent radiation covers the range from 1.3 μm and 1.6 μm, and even broader.

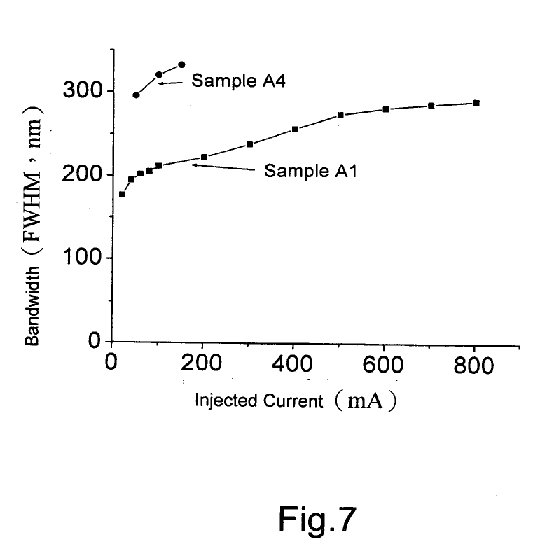

Compare the epitaxy structures of the semiconductor optical amplifier/high luminescent power photodiodes A1 and A4, A4 can accommodate a larger luminescent bandwidth under a low current. FIG. 7 illustrates the relationship of the spectral width at half maximum (FWHM) bandwidth versus injected current. As can be realized from FIG. 7 that A1's FWHM bandwidth will approach 300 nm only on the condition that the injected current reaches approximately to 800 mA, while A4's FWHM bandwidth under the injected current of 50 mA exceeds the A1's FWHM bandwidth under the injected current of 800 mA. When A4 has an injected current larger than or equal to 200 mA, its FWHM bandwidth will exceed 300 nm, which is far wider than the current technology.

Consequently, it is appreciated that the present invention utilizes SCH structures having a shortened width to further uniformize the carrier distribution within the quantum well structures in order to achieve a larger luminescent bandwidth and a low operating current.

To conclude, the present invention contrives a technique of increasing the luminescent bandwidth of the quantum well structures which is realized through the use of multi-layer quantum well structures and SCH structures having a shortened width, and a desirable performance of the photoelectric semiconductor device can be induced as expected.

What is claimed is:

1. A method of increasing the luminescent bandwidth of a photoelectric semiconductor device by separate confinement heterostructure, the method comprising:
controlling the widths of different separate confinement heterostructures and producing multi-layer quantum well structures having different widths or constituent materials with the carrier distribution therein is controlled by either electrons or holes; and
shortening the width of the separate confinement heterostructures in compliance with the mobility of holes, and thereby the, time for the electrons to be captured into the multi-layer quantum well structures is approximate to the time for the holes to be captured into the multi-layer quantum well structures.

2. The method according to claim 1 wherein the relationship between time for holes to enter the multi-layer quantum well structures and the time for electrons to be captured by the quantum well structures is satisfactory for the criterion of: I the time for holes to enter the quantum well structures (τ_{p,diffusion)}—the time for electrons to be captured by the quantum well structure (τ_{n,cap)}|<1 picosecond.

3. The method according to claim 1 wherein the the width of the separate confinement heterostructures is shortened to allow the time for holes to enter the multi-layer quantum well structures to be limited within 5 picoseconds.

4. The method according to claim 1 wherein the energy levels of the multi-layer quantum well structures is sufficient to provide desirable luminescent wavelengths by stacking multi-layer quantum well structures having different widths or constituent materials.

5. The method according to claim 1 wherein the step of shortening the width of the separate confinement heterostructures in compliance with the mobility of holes is accomplished by shortening the separate confinement heterostructures located in the proximity of a P-type semiconductor side to allow the time for holes to reach the multi-layer quantum well structures to be limited within 5 picoseconds.

6. The method according to claim 1 wherein at the step of shortening the width of the separate confinement heterostructures in compliance with the mobility of holes, the width of the separate confinement heterostructures in the proximity of a N-type semiconductor side is larger than the separate confinement heterostructures located in the proximity of the P-type semiconductor side, so as to allow the difference between time for holes to reach the multi-layer quantum well structures and the time for electrons to reach the multi-layer quantum well structures to be limited within 3 picoseconds.

7. The method according to claim 1 wherein the separate confinement heterostructures located in the proximity of P-type semiconductor side includes an extremely thin N-type semiconductor, and wherein a width of the extremely thin N-type semiconductor is not greater than 5 nm and is used to prevent the dopant of the P-type semiconductor from penetrating into the quantum well structures.

8. The method according to claim 1 wherein the following arithmetic model is used to determine which carrier is the dominant carrier:
$${τ}_{LF} = {τ}_{p , diffusion} + {τ}_{n , diffusion} + {τ}_{cap , p} + {τ}_{cap , n} = \frac{{d}_{p}^{2}}{4 {D}_{p}} + \frac{{d}_{n}^{2}}{4 {D}_{n}} + \frac{{d}_{p} {τ}_{cp}}{W} + \frac{{d}_{n} {τ}_{cn}}{W}$$
where dₚ and dₙ respectively represents the distance that the hole or electron diffused to the quantum well, Dₚ and Dₙ represent the diffusion coefficients of semiconductor material, W represents the width of the multi-layer quantum well structures, dₚτ_{cp} and dₙτ_{cn} respectively represent the electron capture time and hole capture time according to the calculation result derived based on quantum physics, and τ_{p,diffusion}, τ_{cap,p}, τ_{n,diffusion}, and _{cap,n} respectively represent the diffusion time of the holes in the separate confinement heterostructure, the diffusion time of the electrons in the separate confinement heterostructure, the equivalent hole capture time of the multi-layer quantum well structures, and the equivalent electron capture time of the multi-layer quantum well structures, and wherein an equivalent carrier capture time of the multi-layer quantum well structures is equal to the product of the carrier capture time of the multi-layer quantum well structures multiplied by a volume ratio of dₚ/W or dₙ/W.

9. The method according to claim 8 wherein the time associated with holes τ_{p,total} is defined as the sum of the diffusion time of the holes in the separate confinement heterostructure plus the equivalent hole capture time of the multi-layer quantum well structures, and is compared with the time associated with electrons τ_{n,total} being defined as the sum of the diffusion time of the electrons in the separate confinement heterostructure plus the equivalent electron capture time of the multi-layer quantum well structures.

10. The method according to claim 9 wherein if τ_{p,total}>τ_{n,total}, electrons are sufficient to enter the two-dimensional energy level of the multi-layer quantum well structures earlier and thereby result in a higher electron density in the proximity of the N-type semiconductor side, and the holes that enters the two-dimensional energy level of the multi-layer quantum well structures later is similarly distributed according to the distribution of the electrons, so that the two-dimensional carrier distribution in the proximity of the N-type semiconductor side within the multi-layer quantum well structures is relatively high.

11. The method according to claim 9 wherein if τ_{n,total}>τ_{p,total}, holes are sufficient to enter the two-dimensional energy level of the multi-layer quantum well structures earlier and thereby result in a higher hole density in the proximity of the P-type semiconductor side, and the electrons that enters the two-dimensional energy level of the multi-layer quantum well structures later is similarly distributed according to the distribution of the holes, so that the two-dimensional carrier distribution in the proximity of the P-type semiconductor side within the multi-layer quantum well structures is relatively high.

12. The method according to claim 9 wherein if τ_{p,total}>τ_{n,total}, holes are selected as the dominant carrier within the multi-layer quantum well structures, so as to obtain a temperature sensitivity and a better temperature coefficient due to the relatively large equivalent mass of holes.

13. The method according to claim 9 wherein if τ_{n,total}>τ_{p,total}, electrons are selected as the dominant carrier within the multi-layer quantum well structures, so as to obtain a relatively uniform carrier distribution within the multi-layer quantum well structures and a relatively larger gain bandwidth.

14. The method according to claim 1 wherein the photoelectric semiconductor device is one of a semiconductor optical amplifier, a superluminescent diode, and a semiconductor laser, and is adapted for III-V semiconductors used in an optical communication system.

15. The method according to claim 1 wherein the separate confinement heterostructure is formed from one group of II-VI semiconductors, III-V semiconductors, and IV semiconductors, combinations of II-VI semiconductors, III-V semiconductors, and IV semiconductors, and optionally includes a plurality of chemical elements.

16. The method according to claim 1 wherein the multi-layer quantum well structures are formed from one group of II-VI semiconductors, III-V semiconductors, and IV semiconductors, and optionally includes a plurality of chemical elements.
